(19) United States
(12) Patent Application Publication
(10) Pub. No.: US 2013/0143392 A1
(43) Pub. Date: Jun. 6, 2013

(54) IN-SITU SIN GROWTH TO ENABLE SCHOTTKY CONTACT FOR GAN DEVICES

(71) Applicants: Linda Romano, Sunnyvale, CA (US); David P. Bour, Cupertino, CA (US); Andrew Edwards, San Jose, CA (US); Hui Nie, Cupertino, CA (US); Isik C. Kizilyalli, San Francisco, CA (US); Richard J. Brown, Los Gatos, CA (US); Thomas R. Prunty, Santa Clara, CA (US)

(72) Inventors: Linda Romano, Sunnyvale, CA (US); David P. Bour, Cupertino, CA (US); Andrew Edwards, San Jose, CA (US); Hui Nie, Cupertino, CA (US); Isik C. Kizilyalli, San Francisco, CA (US); Richard J. Brown, Los Gatos, CA (US); Thomas R. Prunty, Santa Clara, CA (US)

(73) Assignee: EPOWERSOFT, INC., San Jose, CA (US)

(21) Appl. No.: 13/312,055

(22) Filed: Dec. 6, 2011

(51) Int. Cl. H01L 21/20

(52) U.S. Cl. 438/478; 257/E21.09

(57) ABSTRACT

A method of fabricating a diode in gallium nitride (GaN) materials includes providing a n-type GaN substrate having a first surface and a second surface and forming a n-type GaN drift layer coupled to the first surface of the n-type GaN substrate. The method also includes forming an in-situ SiₓN_{y} layer coupled to the n-type GaN drift layer opposite the n-type GaN substrate and at least partially removing portions of the SiₓN_{y} layer and the n-type GaN drift layer to form a plurality of void regions and a remaining portion of the SiₓN_{y} layer. The method further includes selectively regrowing a p-type epitaxial layer in the void regions.

### BACKGROUND OF THE INVENTION

Power electronics are widely used in a variety of applications. Power electronic devices are commonly used in circuits to modify the form of electrical energy, for example, from AC to DC, from one voltage level to another, or in some other way. Such devices can operate over a wide range of power levels, from milliwatts in mobile devices to hundreds of megawatts in a high voltage power transmission system. Despite the progress made in power electronics, there is a need in the art for improved electronics systems and methods of operating the same.

### SUMMARY OF THE INVENTION

The present invention relates generally to electronic devices. More specifically, the present invention relates to forming structures using III-nitride semiconductor materials. Merely by way of example, the invention has been applied to methods and systems for manufacturing semiconductor devices including gallium-nitride (GaN) based layers and one or more layers of in-situ SiN. The methods and techniques can be applied to a variety of compound semiconductor systems such as Schottky diodes, PIN diodes, vertical junction field-effect transistors (JFETs), thyristors, and other devices.

According to an embodiment of the present invention, a method of fabricating a diode in gallium nitride (GaN) materials is provided. The method includes providing a n-type GaN substrate having a first surface and a second surface and forming a n-type GaN drift layer coupled to the first surface of the n-type GaN substrate. The method also includes forming an in-situ SiₓN_{y} layer coupled to the n-type GaN drift layer opposite the n-type GaN substrate and at least partially removing portions of the SiₓN_{y} layer and the n-type GaN drift layer to form a plurality of void regions and a remaining portion of the SiₓN_{y} layer. The method further includes selectively regrowing a p-type epitaxial layer in the void regions.

According to another embodiment of the present invention, a method of fabricating an epitaxial structure is provided. The method includes providing a III-nitride substrate having a first conductivity type, a first surface, and a second surface opposing the first surface and forming a first GaN-based epitaxial layer having a first conductivity type and coupled to the first surface of the III-nitride substrate. The method also includes forming a second GaN-based epitaxial layer over the first GaN-based epitaxial layer. The second GaN-based epitaxial layer has a second conductivity type. The method further includes forming an in-situ protective layer comprising silicon and nitrogen. The in-situ protective layer is coupled to the second GaN-based epitaxial layer opposite the first GaN-based epitaxial layer. The method additionally includes at least partially removing portions of the in-situ protective layer and the second GaN-based epitaxial layer to form at least one gate structure, removing a remaining portion of the in-situ protective layer, and forming a first metallic structure coupled to the gate structure.

Numerous benefits are achieved by way of the present invention over conventional techniques. For example, embodiments of the present invention enable improved protection and layer regrowth options in comparison with conventional techniques. Additionally, the use of deposition and complete or partial removal of SiN layers, in combination with regrowth and etching techniques detailed herein, may provide enhanced dimensional accuracy over conventional techniques. These and other embodiments of the invention, along with many of its advantages and features, are described in more detail in conjunction with the text below and attached figures.

### BRIEF DESCRIPTION OF THE DRAWINGS

FIG. 1 is a simplified flowchart illustrating a method of fabricating a Schottky diode using an in-situ SiN layer according to an embodiment of the present invention;

FIGS. 2-7 are simplified cross-sectional diagrams illustrating fabrication of a Schottky diode using an in-situ SiN layer according to an embodiment of the present invention;

FIGS. 8-10 are simplified cross-sectional diagrams illustrating a method of fabricating a Schottky diode with edge termination structures formed through etching of an epitaxial layer according to an embodiment of the present invention;

FIG. 11 is a simplified cross-sectional diagram illustrating a vertical JFET structure be formed according to an embodiment of the present invention;

FIG. 12 is a simplified flowchart illustrating a method of fabricating a p-GaN Enhancement Mode HEMT using an in-situ SiN layer according to an embodiment of the present invention;

FIGS. 13-16 are simplified cross-sectional diagrams illustrating the fabrication of a p-GaN Enhancement Mode HEMT using an in-situ SiN layer according to an embodiment of the present invention; and

FIG. 17 is a simplified cross-sectional diagram illustrating a PIN diode formed according to an embodiment of the present invention.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF SPECIFIC EMBODIMENTS

Embodiments of the present invention relate to electronic devices. More specifically, the present invention relates to forming semiconductor devices including gallium-nitride (GaN) based layers and one or more layers of in-situ SiN. Merely by way of example, the invention has been applied to methods and systems for manufacturing diode structures using gallium-nitride (GaN) based epitaxial layers. The methods and techniques can be applied to form a variety of types of structures for numerous types of semiconductor devices, including, but not limited to, junction field-effect transistors (JFETs), diodes, thyristors, vertical field-effect transistors, thyristors, and other devices, including merged PIN, Schottky diodes, and the like.

GaN-based electronic and optoelectronic devices are undergoing rapid development, and generally are expected to outperform competitors in silicon (Si) and silicon carbide (SiC). Desirable properties associated with GaN and related alloys and heterostructures include high bandgap energy for visible and ultraviolet light emission, favorable transport properties (e.g., high electron mobility and saturation velocity), a high breakdown field, and high thermal conductivity. In particular, electron mobility, μ, is higher than competing materials for a given background doping level, N. This provides low resistivity, ρ, because resistivity is inversely proportional to electron mobility, as provided by equation (1):

$$ρ = \frac{1}{q μ N} , \qquad ( 1 )$$

where q is the elementary charge.

Another superior property provided by GaN materials, including homoepitaxial GaN layers on bulk GaN substrates, is high critical electric field for avalanche breakdown. A high critical electric field allows a larger voltage to be supported over smaller length, L, than a material with a lower critical electric field. A smaller length for current to flow together with low resistivity give rise to a lower resistance, R, than other materials, since resistance can be determined by equation (2):

$$R = \frac{ρ L}{A} , \qquad ( 2 )$$

where A is the cross-sectional area of the channel or current path.

A Schottky diode is formed by an interface between lightly n-type doped GaN and a metal with a larger work function than the GaN, such as nickel. In order to fully utilize the high critical field properties of GaN, edge termination can be utilized for the Schottky contact to avoid premature breakdown between the underlying n-GaN and the Schottky metal at the metal corner. In order to form a field plate for edge termination, an insulator may be utilized on the GaN surface. According to aspects of the present invention, in-situ SiN may be utilized for this layer, or as a part of this layered structure. According to other aspects of the invention, an in-situ SiN layer may be partially removed prior to selective regrowth of an additional layer, such as a p+ GaN regrowth layer.

The inventors have determined that many GaN-based devices may benefit from in-situ SiN deposition, for example, immediately following growth of a final (Al)GaN layer. The SiN layer may be used to protect the (Al)GaN, or other, surface from contamination during device processing. For example, during processing, GaN and/or AlGaN surfaces and the like, may advantageously be maintained in-situ while a SiN layer is deposited, and the SiN layer may be maintained during subsequent processing steps that may include air exposure, etching environments, and/or chemical contamination, any of which may damage exposed GaN and/or AlGaN surfaces. In some embodiments, the SiN, or portions thereof, may be removed as necessary, for example prior to deposition of a metal to form a Schottky contact. Devices that may be fabricated according to such methods may include, for example, Schottky barrier diodes, PiN diodes, thyristors, and many variations of transistors including JFETS, MISFETS, HEMTs, and the like. The following non-limiting examples describe a few such devices that may include a SiN layer grown in the reactor, e.g. after III-N growth.

According to embodiments of the present invention, the use of an in-situ SiN layer following growth of an n-GaN layer, for example, may beneficially protect the surface during the entire device process, e.g., up until deposition of a Schottky metal. The in-situ SiN layer can be referred to as an in-situ protective layer. In a particular embodiment, the in-situ SiN material can be partially or wholly removed prior to the metal deposition process for the Schottky contact, e.g., by wet or dry etching using KOH or CF₄ plasma.

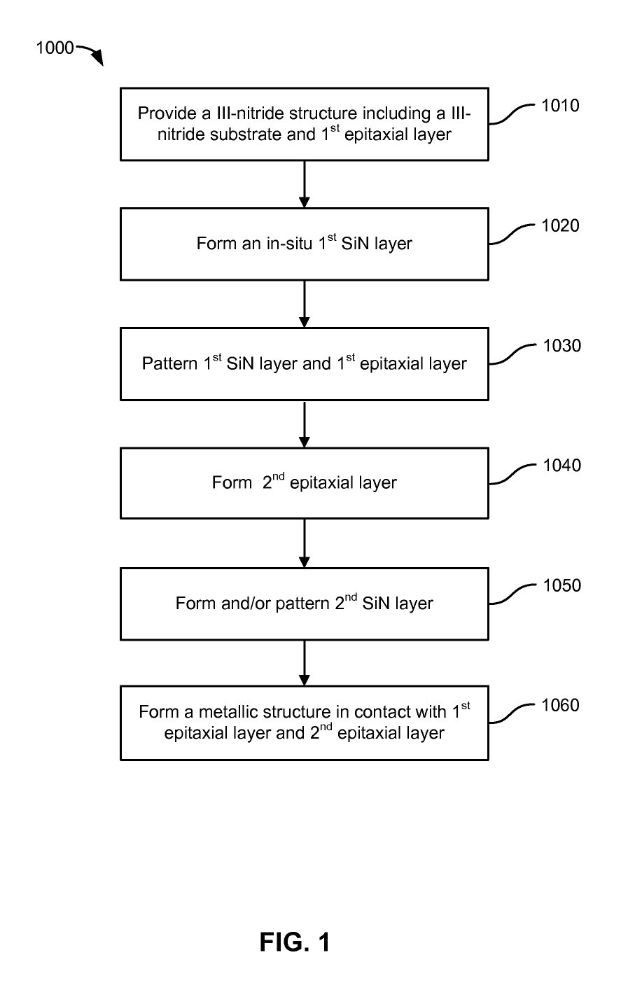

FIG. 1 is a simplified flowchart illustrating a method of fabricating a Schottky diode using an in-situ SiN layer according to an embodiment of the present invention. As an example, the process flow illustrated in FIG. 1 could be used during portions of the fabrication of a GaN Merged PiN, Schottky (MPS) Diode using an in-situ SiN layer. As shown in FIG. 1, the method 1000 may begin by forming a first GaN epitaxial drift layer on a substrate (1010), such as heavily doped n-type GaN substrate.

A SiN layer is formed in-situ, i.e., in the growth reactor, and is coupled to the GaN drift layer (1020). The SiN layer may be deposited according to techniques known in the art, and may include, for example, Si₃N₄, SiNₓ or other compositions. Thus, the use of the term “SiN” layer is intended to include all compositions of materials including silicon and nitrogen in stoichiometric and other proportions. In embodiments, the in-situ SiN layer may be formed, for example, using silane from a doping source or a separate direct silane source or any Si precursor. Reactive N₂ is also typically provided in the form of NH₃ that would be already present for GaN growth. In some embodiments, an additional ex-situ SiO₂, oxynitride, or Al₂O₃ layer may be applied to the in-situ SiN layer, or remaining portions of the SiN layer, e.g., to provide even further selectivity for subsequent regrowth steps or the like. Other in-situ layers could include a lower temperature polycrystalline GaN or AN layer that could easily be removed by wet etching after processing.

The method 1000 also includes patterning portions of the SiN layer and the first epitaxial layer (1030), and optionally removing portions of the SiN layer and underlying portions of the GaN drift layer, e.g., to form windows in which a p+ GaN layer may be regrown during later stages of the fabrication process. The patterned removal of portions of the SiN layer and the GaN drift layer may be accomplished, for example, by etching and other techniques known in the art. The removal of portions of the SiN layer and the GaN drift layer may result in a plurality of epitaxial structures.

The method additionally includes forming another epitaxial layer, such as a regrown p+ GaN layer, for example, in the areas not covered by the remaining SiN layer (1040). That is, a GaN layer may be regrown as a second epitaxial layer in the portions, in plan view, no longer coated with SiN.

The method further includes forming an additional SiN layer over the second epitaxial layer and optionally patterning this layer and the remaining SiN and/or GaN drift layer (1050). In embodiments, the additional SiN layer may be formed in-situ without breaking chamber from S1020. The remaining SiN from the initial in-situ layer may be removed prior to forming the additional SiN layer, or it may be subsumed in the additional SiN layer. The additional SiN layer may formed as a blanket coating, and may also be etched, or otherwise patterned, as needed, for formation of additional structures, such as contacts, etc.

The method also includes forming additional structures (e.g., metallic structures) over the second SiN layer and/or any exposed portions of the regrown GaN layer and/or GaN drift layer (1060). For example, a metallic structure suitable for use as a Schottky contact may be formed in contact with the exposed portions of the regrown GaN layer and the GaN drift layer, e.g., in a space where the new SiN layer has been etched away. Other structures may also be formed including, for example, various edge termination structures, or the like.

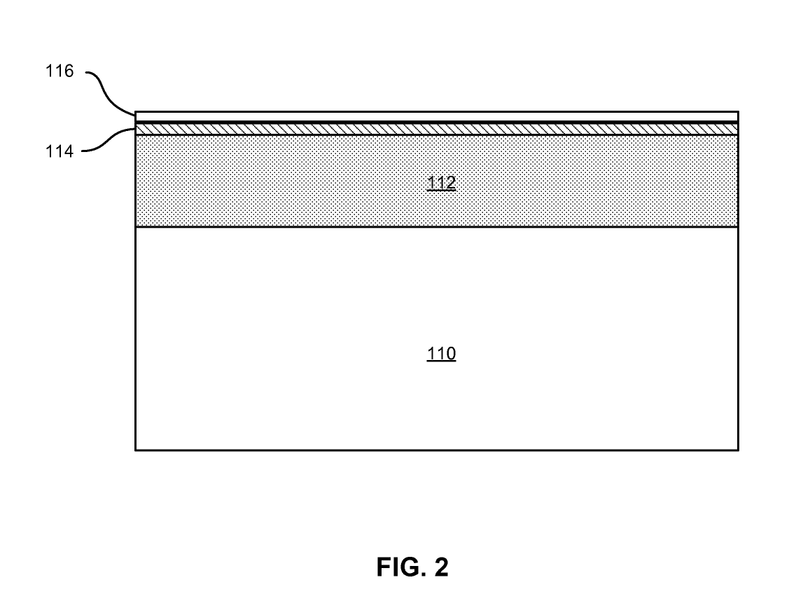

It should be appreciated that the specific steps illustrated in FIG. 1 provide a particular method of fabricating a Schottky diode using an in-situ SiN layer according to an embodiment of the present invention. Other sequences of steps may also be performed according to alternative embodiments. For example, alternative embodiments of the present invention may perform the steps outlined above in a different order. Moreover, the individual steps illustrated in FIG. 1 may include multiple sub-steps that may be performed in various sequences as appropriate to the individual step. Furthermore, additional steps may be added or removed depending on the particular applications. One of ordinary skill in the art would recognize many variations, modifications, and alternatives. Additional details of an exemplary fabrication process are depicted in FIGS. 2-7.

As shown in FIG. 2, a first GaN epitaxial layer 112 is coupled to (e.g., formed in contact with) a GaN substrate 110 having the same conductivity type. Although a GaN substrate is illustrated in some embodiments, other III-nitride materials including AlN, InGaN, AlGaN, InAlGaN, doped versions of the same, combinations thereof, and the like, are included within the scope of the present invention. The GaN substrate 110 can be a pseudo-bulk or bulk GaN material on which the first GaN epitaxial layer 112 is grown. Dopant concentrations (e.g., doping density) of the GaN substrate 110 can vary, depending on desired functionality. For example, a GaN substrate 110 can have an n+ conductivity type, with dopant concentrations ranging from 1×10¹⁷ cm⁻³ to 1×10²⁰ cm⁻³. In other embodiment, the substrate can be p-type or semi-insulating. Although the GaN substrate 110 is illustrated as including a single material composition, multiple layers can be provided as part of the substrate. Moreover, adhesion, buffer, and other layers (not illustrated) can be utilized during the epitaxial growth process. One of ordinary skill in the art would recognize many variations, modifications, and alternatives.

The properties of the first GaN epitaxial layer 112 can also vary, depending on desired functionality. As discussed further herein, the first GaN epitaxial layer 112 can serve as a drift region for the Schottky diode, and therefore can be a relatively low-doped material. For example, the first GaN epitaxial layer 112 can have an n−conductivity type, with dopant concentrations ranging from 1×10¹⁴ cm⁻³ to 1×10¹⁸ cm⁻³. Furthermore, the dopant concentration can be uniform, or can vary, for example, as a function of the thickness of the drift region.

The thickness of the first GaN epitaxial layer 112 can also vary substantially, depending on the desired functionality. As discussed above, homoepitaxial growth can enable the first GaN epitaxial layer 112 to be grown far thicker than layers formed using conventional methods. In general, in some embodiments, thicknesses can vary between 0.5 μm and 100 μm, for example. In other embodiments thicknesses are greater than 5 μm. Resulting parallel plane breakdown voltages for the Schottky diode 100 can vary depending on the embodiment. Some embodiments provide for breakdown voltages of at least 100V, 300V, 600V, 1.2 kV, 1.7 kV, 3.3 kV, 5.5 kV, 13 kV, or 20 kV.

Different dopants can be used to create n- and p-type GaN epitaxial layers and structures disclosed herein. For example, n-type dopants can include silicon, oxygen, or the like. P-type dopants can include magnesium, beryllium, calcium zinc, or the like.

As also shown in FIG. 2, a first SiN layer 114 may be deposited, or otherwise formed, in-situ over or on the first GaN epitaxial layer 112. Various deposition techniques may be used for in-situ deposition as will be appreciated by those of skill in the art. The inventors have determined that in-situ deposition of the SiN layer on the GaN epitaxial layer may be advantageous in, for example, to protecting the GaN surface during the device fabrication process up to and until deposition of the Schottky metal. Embodiments of the present invention are not limited to this particular implementation and use of the in-situ SiN layer as a protection layer during different portions of the device fabrication process are included within the scope of the present invention.

The inventors have determined that structural damage may be present at the interface of subsequently regrown layers due, for example, to the fact that GaN-based materials are quite hard and present issues for the etching processes that are commonly used, sometimes utilizing a significant sputtering component. Therefore, for example, regrowth of a p-type GaN layer on an n-type GaN surface may result in the formation of a p-n junction that is characterized by less than optimal electrical characteristics including leakage currents. Without limiting embodiments of the present invention, the inventors believe that in-situ formation of a SiN layer, which may be partially or totally removed later, over the GaN epitaxial layer used as the regrowth surface can be effective in protecting the GaN layer and result in better junction formation during regrowth or other growth processes.

FIG. 2 also depicts an optional oxide layer 116 formed over, and optionally in contact with, the first SiN layer 114. Optional oxide layers, such as oxide layer 116 (e.g., SiₓO_{y} or SiₓO_{y}N_{z}) may be used, for example, to improve selectivity of subsequent regrowth layers, such as those discussed herein. Since oxide layer 116 is optional it is not illustrated in some subsequent drawings.

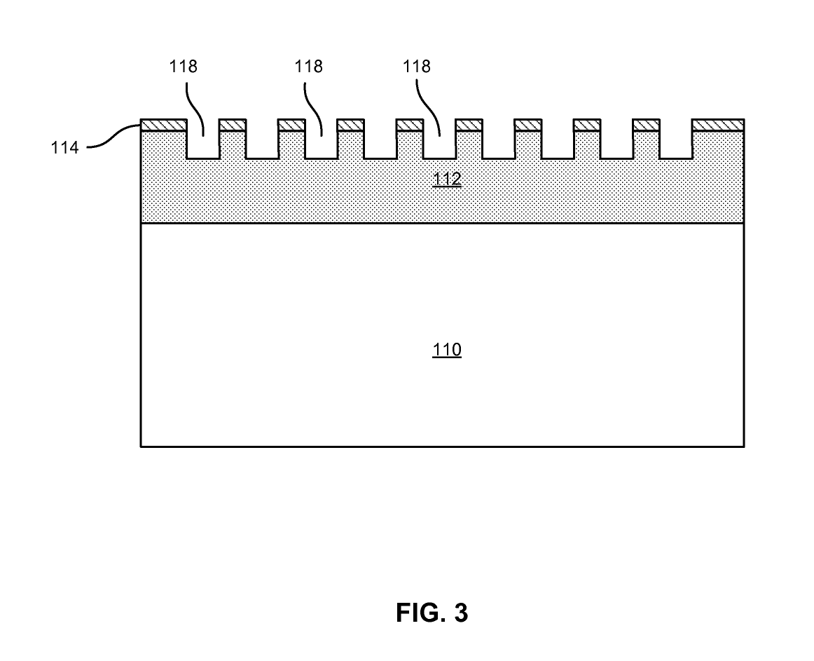

Referring to FIG. 3, a plurality of recesses 118 may be etched, or otherwise formed, through the SiN layer 114 and, optionally, into the first GaN epitaxial layer 112. The shape and/or pattern of the recesses 118 is a function of the particular devices to be fabricated, details of the etching process, and the like, and will vary depending on the particular application.

Although a plurality of recessed trenches are illustrated in FIG. 3, embodiments of the present invention are not limited to this particular shape and pattern, and other shapes and patterns can be employed. As illustrated in FIG. 3, the etch process may be a substantially anisotropic etch with little to no undercutting under the SiN layer 114. In other embodiments, some undercutting associated with an isotropic etch component may be observed. Isotropic etching is a viable process for some embodiments of the present invention. In the embodiment shown in FIG. 3, a plurality of n-type GaN structures are formed with SiN layer caps, which may be used to facilitate a subsequent GaN regrowth process as discussed further below.

It should be noted that the recesses 118, and other structural features related to partial removal of epitaxial layers, may be variously sized depending on, for example, specific structure and device parameters. According to various embodiments described herein, epitaxial structures can be sized and spaced to form edge termination structures, while other epitaxial structures may be used to form p-type contacts or buried structures. For example, according to some embodiments, p-type contacts can range from 2 μm to 20 μm wide, and buried structures can range from 0.5 μm to 10 μm wide. Additionally, according to some embodiments, the distance between buried structures and/or contacts can range from 0.2 μm to 10 μm in length. In some embodiments, an n-type epitaxial regrowth layer may be used to control potential between floating p-type edge termination structures. One of ordinary skill in the art would recognize such passivation can be utilized in other embodiments provided herein.

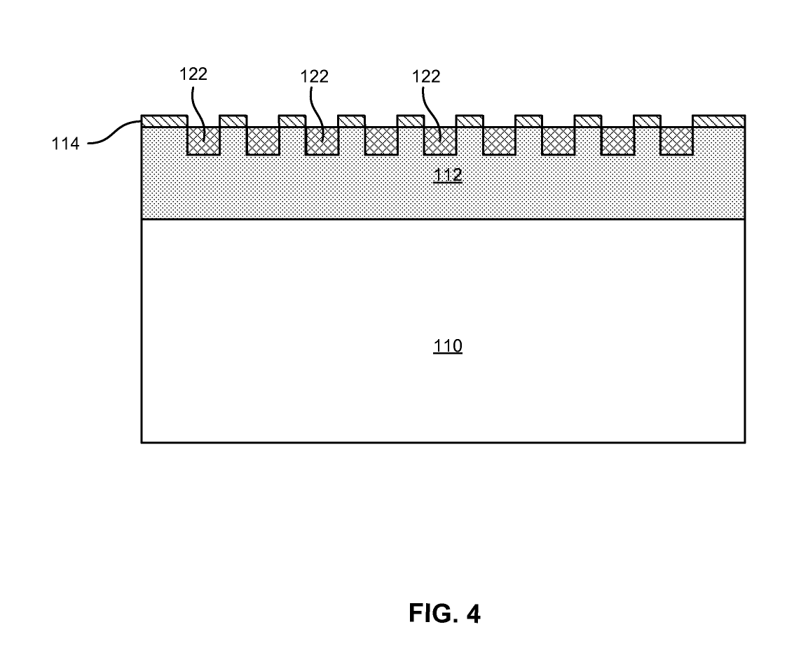

Referring to FIG. 4, a selective regrowth process is used to form a second GaN epitaxial layer 122 in the recesses 118 but, in the illustrated embodiment, not over the SiN layer 114. For example, a p+ GaN regrowth may be provided that is selective to growth on the underlying n-GaN drift layer and not on the SiN layer. The regrowth process can provide a p-type material in contact with an n-type material as well as an n-type material in contact with a p-type material. As discussed above, additional layers that increase regrowth selectivity can be utilized as appropriate to the particular application. One of ordinary skill in the art would recognize many variations, modifications, and alternatives.

FIG. 4 illustrates the formation of a second GaN epitaxial layer 122 above the first GaN epitaxial layer 112, but embodiments of the present invention are not limited to these particular materials. The second GaN epitaxial layer 122 can have a conductivity type different than the first GaN epitaxial layer 112. For instance, if the first GaN epitaxial layer 112 is formed from an n-type GaN material, the second GaN epitaxial layer 122 can be formed from a p-type GaN material, and vice versa. In some embodiments, portions of the second GaN epitaxial layer 122 may be used to form the edge termination and/or other structures by continuous regrowth over portions of the first GaN epitaxial layer 112 with other portions of the structure, such as regions of other semiconductor devices, characterized by reduced or no regrowth as a result of the presence of a regrowth mask provided by the remaining SiN layer 114, and/or optional oxide layer 116. That is, as can be seen in FIG. 4, the second GaN epitaxial layer 122 may be selectively regrown in the voids 118 formed by removal of the SiN layer 114 and portions of the first GaN epitaxial layer 112. Thus, an interdigitated or other pattern of n-type and p-type materials may be formed utilizing embodiments of the present invention.

The thickness of the second GaN epitaxial layer 122 can vary, depending on the process used to form the layer and the device design. In some embodiments, the thickness of the second GaN epitaxial layer 122 is between 0.1 μm and 5 μm. In other embodiments, the thickness of the second GaN epitaxial layer 122 is between 0.3 μm and 1 μm.

The second GaN epitaxial layer 122 can be highly doped, for example in a range from about 5×10¹⁷ cm⁻³ to about 1×10¹⁹ cm⁻³. Additionally, as with other epitaxial layers, the dopant concentration of the second GaN epitaxial layer 122 can be uniform or non-uniform as a function of thickness. In some embodiments, the dopant concentration increases with thickness, such that the dopant concentration is relatively low near the first GaN epitaxial layer 112 and increases as the distance from the first GaN epitaxial layer 112 increases. Such embodiments provide higher dopant concentrations at the top of the second GaN epitaxial layer 122 where metal contacts can be subsequently formed. Other embodiments may utilize heavily doped contact layers (not shown) to form ohmic contacts.

One method of forming the second GaN epitaxial layer 122, and other layers described herein, can be through a regrowth process that uses an in-situ etch and diffusion preparation processes. These preparation processes are described more fully in U.S. patent application Ser. No. 13/198,666, filed on Aug. 4, 2011, the disclosure of which is hereby incorporated by reference in its entirety.

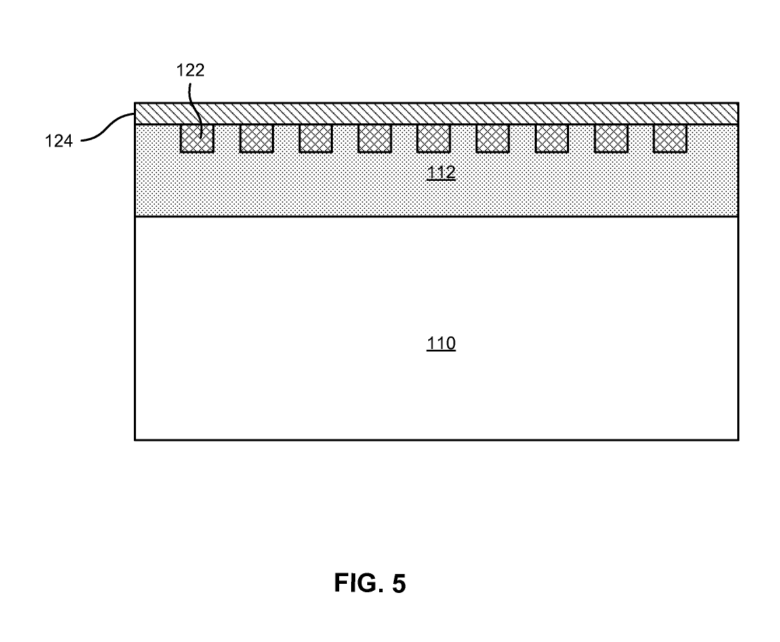

Referring to FIG. 5, a second SiN layer 124 is deposited over the first GaN epitaxial layer 112 and second GaN epitaxial layer 122. It should be noted that the remaining SiN from SiN layer 114 may be removed prior to forming SiN layer 124, or the remaining SiN from SiN layer 114 may be subsumed in SiN layer 124. SiN layer 124 may formed as a blanket coating, or by using other techniques known in the art, depending on a desired configuration of the SiN layer 124, such as patterning for contacts discussed herein.

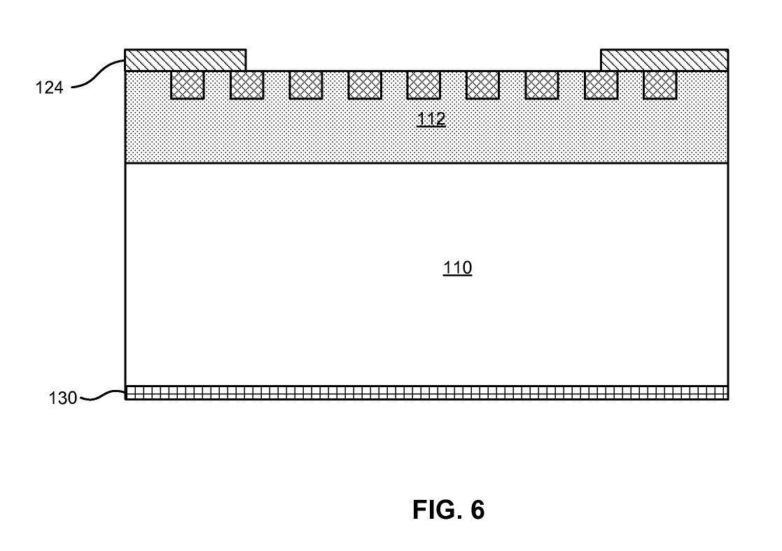

FIG. 6 illustrates removal of a portion of SiN layer 124, e.g. by etching, to re-expose portions of the first GaN epitaxial layer 112 and second GaN epitaxial layer 122, and formation of an metal layer 130. Portions of the SiN layer 124 may be removed, for example, to provide contact areas for Schottky contacts and other metallic structures. It should be noted that, although SiN layer 124 is depicted as a covering layer, that is then patterned, other techniques of forming a patterned layer are also possible, such as combined depositing and patterning of the layer through a mask or the like.

Metal layer 130 may be, for example, one or more layers of ohmic metal that serve as a contact for the cathode of a Schottky diode. For example, the metal layer 130 can comprise a titanium-aluminum (Ti/Al) ohmic metal. Other metals and/or alloys can be used including, but not limited to, aluminum, nickel, gold, combinations thereof, or the like. In some embodiments, an outermost metal of the metal layer 130 can include gold, tantalum, tungsten, palladium, silver, or aluminum, combinations thereof, and the like. The metal layer 130 can be formed using any of a variety of methods such as sputtering, evaporation, or the like.

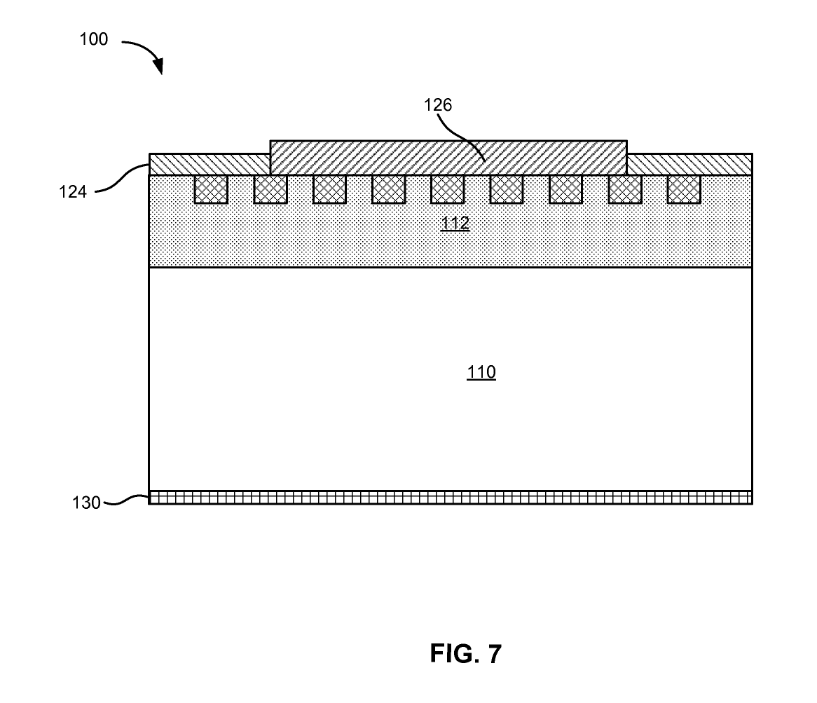

FIG. 7 illustrates the formation of a metallic structure 126 on the exposed portion of the first GaN epitaxial layer 112 and second GaN epitaxial layer 122. The metallic structure 126 can be one or more layers of metal and/or alloys to create a Schottky contact. The metallic structure 126 can be formed using a variety of techniques known to those of skill in the art, which can vary depending on the metals used. In some embodiments, the metal structure 126 can include, for example, nickel, platinum, palladium, silver, gold, and the like.

The device 100 illustrated in FIG. 7, provides a lateral p-n junction formed between the material of the n-type first GaN epitaxial layer 112 and the regrown material in second GaN epitaxial layer 122. The lateral p-n junction includes depletion regions with a generally vertical orientation that are orthogonal to surface of the substrate 110. Thus, the term “lateral junction” or “lateral p-n junction” indicates current flow in a lateral direction across the junction. Although this orientation is illustrated in FIG. 7, other embodiments can utilize different geometries as appropriate to the particular implementation.

Although some embodiments, such as that depicted in FIGS. 2-7, are discussed in terms of GaN substrates and GaN epitaxial layers, the present invention is not limited to these particular binary III-V materials and is applicable to a broader class of III-V materials, in particular III-nitride materials. Additionally, although a GaN substrate is illustrated in FIGS. 2-7, embodiments of the present invention are not limited to GaN substrates. Other III-V materials, in particular, III-nitride materials, are included within the scope of the present invention and can be substituted not only for the illustrated GaN substrate, but also for other GaN-based layers and structures described herein. As examples, binary III-V (e.g., III-nitride) materials, ternary III-V (e.g., III-nitride) materials such as InGaN and AlGaN, quaternary III-nitride materials, such as AlInGaN, doped versions of these materials, and the like are included within the scope of the present invention.

The fabrication process illustrated in FIGS. 2-7 utilizes a process flow in which an n-type drift layer is grown using an n-type substrate. However, the present invention is not limited to this particular configuration. In other embodiments, substrates with p-type doping are utilized. Additionally, embodiments can use materials having an opposite conductivity type to provide devices with different functionality. Thus, although some examples relate to the growth of n-type GaN epitaxial layer(s) doped with silicon, in other embodiments the techniques described herein are applicable to the growth of highly or lightly doped material, p-type material, material doped with dopants in addition to or other than silicon such as Mg, Ca, Be, Ge, Se, S, O, Te, and the like. The substrates discussed herein can include a single material system or multiple material systems including composite structures of multiple layers. One of ordinary skill in the art would recognize many variations, modifications, and alternatives.

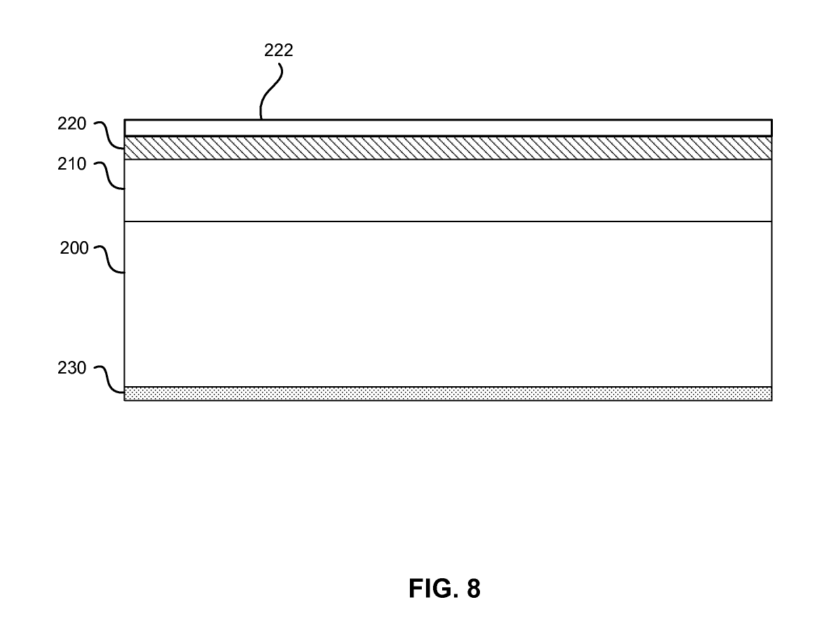

It should also be noted that the inventive concepts described herein can be applied to various devices where, for example, an in-situ SiN layer can be deposited after a GaN layer, and then subsequently completely or partially removed during device processing. In the example provided in FIGS. 2-7, the SiN layer can be used to protect the GaN layer throughout processing including a GaN regrowth phase since SiN acts as a regrowth mask for the regrowth of GaN. Some additional examples of such structures are shown in FIGS. 8-10 and FIG. 11.

FIG. 8 illustrates a simplified cross sectional view of a first GaN epitaxial layer 210 coupled to (e.g., formed on) a GaN substrate 200 having the same conductivity type as the first GaN epitaxial layer 210. As indicated above, the GaN substrate 200 can be a pseudo-bulk or bulk GaN material on which the first GaN epitaxial layer 210 is grown and is not limited to GaN, but is intended to represent III-nitride materials. A second GaN epitaxial layer 220 is formed above the first GaN epitaxial layer 210. The second GaN epitaxial layer 220, from which edge termination structures are eventually formed as described below, can have a conductivity type different than the first GaN epitaxial layer 210. For instance, if the first GaN epitaxial layer 210 is formed from an n-type GaN material, the second GaN epitaxial layer 220 can be formed from a p-type GaN material, and vice versa. In some embodiments, the second GaN epitaxial layer 220 used to form edge termination structures is a continuous regrowth over portions of the first GaN epitaxial layer 210 with other portions of the structure, such as regions of other semiconductor devices, characterized by reduced or no growth as a result of the presence of a regrowth mask (not shown). One of ordinary skill in the art would recognize many variations, modifications, and alternatives.

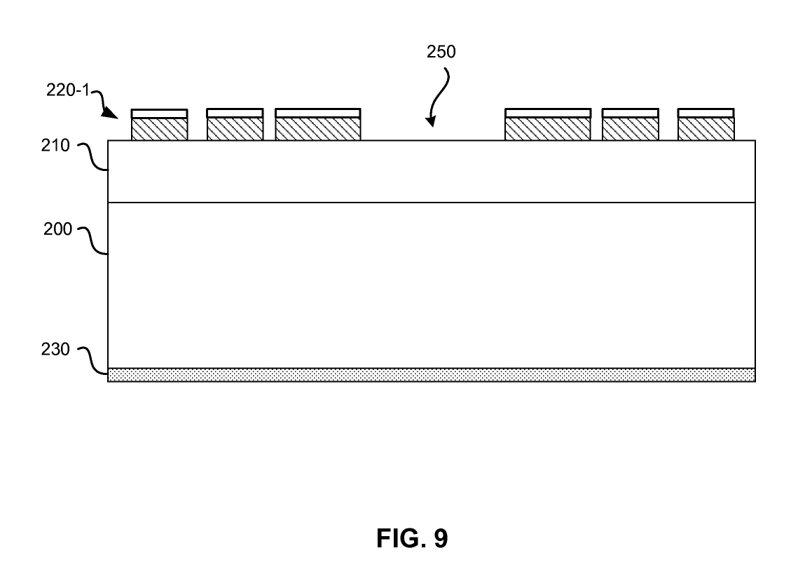

According to aspects of the invention, an in-situ SiN layer 222 is also be provided over second GaN epitaxial layer 220. As shown in FIG. 9, the SiN layer 222 and second GaN epitaxial layer 220 may be patterned in order to form edge termination structures 220-1, which are patterned and formed from the second GaN epitaxial layer 220 and the in-situ SiN layer 222. As discussed in further detail throughout the present specification, edge termination structures 220-1 can include any of a variety of structures, such as guard rings that circumscribe a Schottky diode to provide edge termination. Additionally, as illustrated in FIG. 9, at least a portion of the SiN layer 222 and second GaN epitaxial layer 220 may be removed to form an exposed portion 250 of the first GaN epitaxial layer 210 within which a Schottky diode can subsequently be formed. The removal can be performed by a controlled etch using an etch mask (not shown but having the dimensions of the edge termination structures 220-1) designed to stop at approximately the interface between the second GaN epitaxial layer 220 and the first GaN epitaxial layer 210. Inductively-coupled plasma (ICP) etching and/or other common GaN etching processes can be used. In the illustrated embodiment, the material removal process used to remove portions of the SiN layer 222 and second GaN epitaxial layer 220 terminates at the interface of layers 220 and layer 210, however, in other embodiments, the process terminates at a different depth, for example, extending into or leaving a portion of the first GaN epitaxial layer 210.

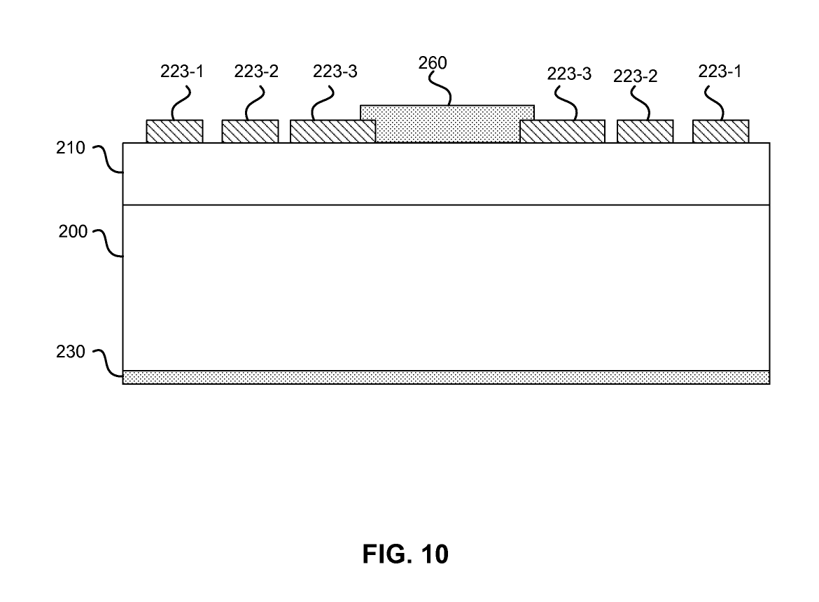

FIG. 10 illustrates the formation of a metallic structure 260 on the exposed portion 250 of the first GaN epitaxial layer 210. As shown in FIG. 10, remaining portions of the SiN layer 222 have been removed prior to formation of the metallic structure 260 to form edge termination elements 223-1 through 223-3. However, it should also be noted that portions of the SiN layer 222 may be present during formation of the metallic structure 260, depending on, for example, materials, processing parameters, etc. The metallic structure 260 can be one or more layers of metal and/or alloys to create a Schottky barrier with the first GaN epitaxial layer 210, and the metallic structure 260 further can overlap portions of the nearest edge termination element 223-3. The metallic structure 260 can be formed using a variety of techniques, including lift-off and/or deposition with subsequent etching, which can vary depending on the metals used. In some embodiments, the metal structure 260 can include nickel, platinum, palladium, silver, gold, and the like.

FIG. 10 illustrates a metallic structure 260 electrically coupled to a first III-nitride epitaxial layer, e.g. first GaN epitaxial layer 210, to create a Schottky contact between the metallic structure 260 and the first III-nitride epitaxial layer, which forms the drift layer of the Schottky diode. Moreover, as illustrated in FIG. 10, a backside ohmic metal 230 can formed on a first surface of a III-nitride substrate, e.g., GaN substrate 200, opposing a surface of the III-nitride substrate coupled to the first III-nitride epitaxial layer, e.g. first GaN epitaxial layer 210, providing a cathode for the Schottky diode. The various epitaxial layers used to form the Schottky diode and edge termination structures do not have to be uniform in dopant concentration as a function of thickness, but may utilize varying doping profiles as appropriate to the particular application.

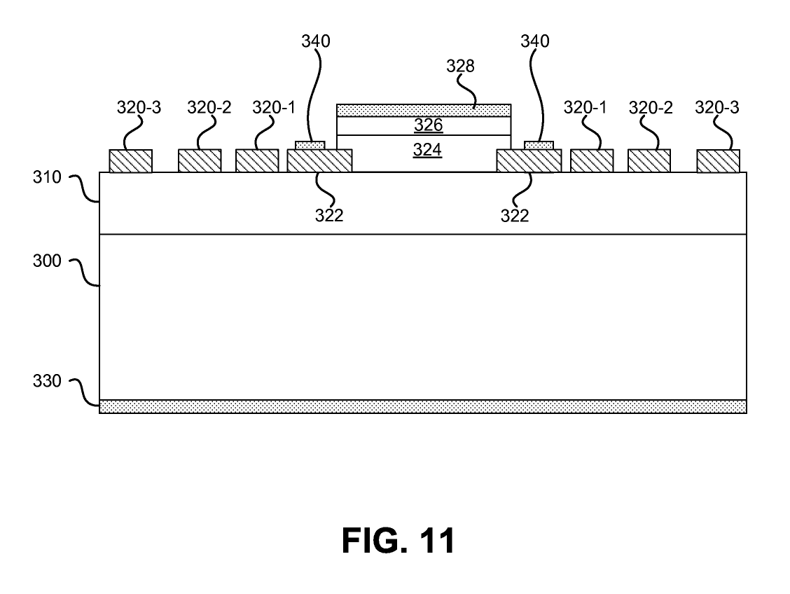

FIG. 11 shows a simplified cross sectional view of a device that shares some similarities with the device illustrated in FIG. 10 and may be manufactured according to processes as described herein. In particular, FIG. 11 shows a vertical JFET structure formed according to aspects of the present invention. The vertical JFET includes a GaN substrate 300, first GaN epitaxial layer 310, and metallic layer 330, similar to those in the structures discussed previously. Here, metallic layer 330 can function as a drain contact of the vertical JFET. Additionally, the JFET can include a channel region 324, which can be formed through epitaxial regrowth and have a low dopant concentration similar to the first GaN epitaxial layer 310, having the same conductivity type. Furthermore, a source region 326 can be formed from an epitaxial layer of the same conductivity type as the channel region 324 and the first GaN epitaxial layer 310. Gate regions 322 can be formed from the same epitaxial growth or regrowth as the edge termination structures 320, which have an opposite conductivity type to the first GaN epitaxial layer 310. Any number between one to seven or more edge termination structures 320 can be formed to provide edge termination for the JFET. Furthermore, the edge termination structures 320 can be shaped any of a variety of ways, according to the physical characteristics of the JFET and other considerations. Finally, ohmic metal contacts 340 and 328 can be provided on the gate regions 322 and the source region 326 to provide gate and source contacts, respectively. Additional description related to JFETs is provided in U.S. patent application Ser. No. 13/198,655, filed on Aug. 4, 2011, the disclosure of which is hereby incorporated by reference in its entirety for all purposes.

For example, in some embodiments, the GaN substrate 300 can have an n+ conductivity type with dopant concentrations ranging from 1×10¹⁷ cm⁻³ to 1×10¹⁹ cm⁻³, and the first GaN epitaxial layer 310 can have a n−conductivity type, with dopant concentrations ranging from 1×10¹⁴ cm⁻³ to 1×10¹⁸ cm³. The thickness of the first GaN epitaxial layer 310 can be anywhere from 0.5 μm and 100 μm or over 100 μm, depending on desired functionality and breakdown voltage. The channel region 324, which can have a n− conductivity type with a dopant concentration similar to the first GaN epitaxial layer 310, can be anywhere from between 0.1 μm and 10 μm thick, and the width of the channel region 324 (i.e., the distance between gate regions 322) for a normally-off vertical JFET can be between 0.5 μm and 10 μm. For a normally-on vertical JFET, the width of the channel region 324 can be greater. The source region 326 can have a thickness of between 500 Å and 5 μm and an n-type conductivity with a dopant concentration equal to or greater than 1×10¹⁸ cm³. The gate regions 322 and the edge termination structures 320-1, 320-2, 320-3 can be from 0.1 μm and 5 μm thick and have a p+ conductivity type with dopant concentrations in a range from about 1×10¹⁷ cm⁻³ to about 1×10¹⁹ cm⁻³. Gate regions 322 and the edge termination structures 320-1, 320-2, 320-3 may be formed as discussed herein using various applications and removal of an in-situ SiN layer.

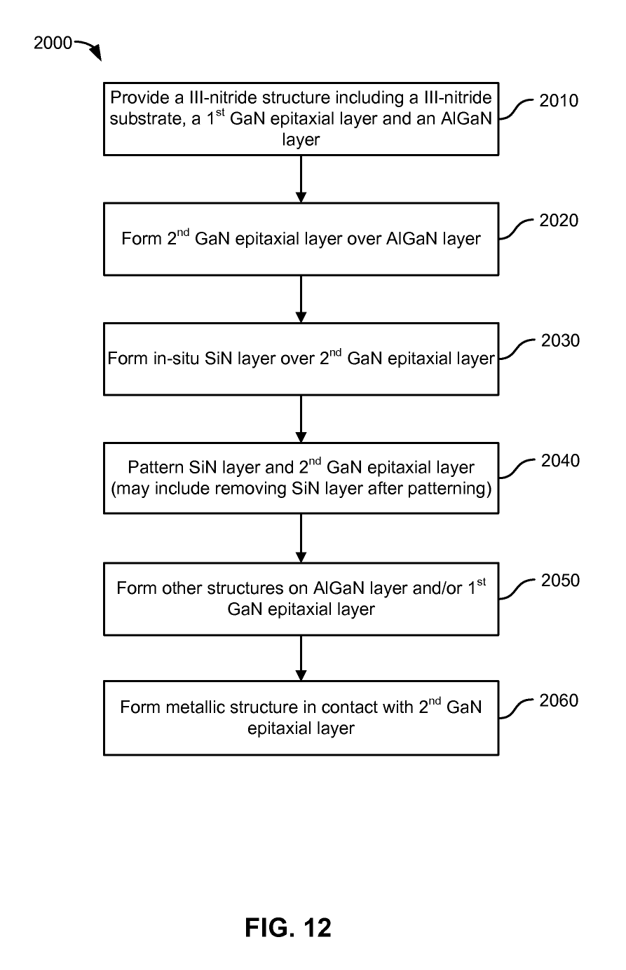

FIG. 12 is a simplified flowchart illustrating a method of fabricating a p-GaN Enhancement Mode HEMT using an in-situ SiN layer according to an embodiment of the present invention. While certain aspects of the process shown in FIG. 12 may be described with reference to a p-GaN enhancement Mode HEMT including a AlGaN epitaxial layer, the method should not be interpreted as limited to such embodiments alone.

As shown in FIG. 12, the method 2000 includes forming a first GaN epitaxial layer having a first conductivity type coupled to a substrate (2010), such as a GaN substrate. Other layers may also be formed on the first GaN epitaxial layer during the process, such as, for example, an AlGaN epitaxial layer, which may be used in a 2D electron layer in an HEMT structure and/or as an etch stop layer, or the like.

The method also includes forming a second GaN epitaxial layer having a second conductivity type over the first GaN epitaxial layer (2020). For instance, if the first conductivity type is an n-type conductivity, the second conductivity type can be a p-type conductivity, and vice versa. The second GaN epitaxial layer may be coupled to, for example, an AlGaN layer, or etch stop layer, if present. In some embodiments, the second GaN epitaxial layer may be used to form gate, edge termination, or other structures, and may be a continuous regrowth over the AlGaN layer and/or portions of the first GaN epitaxial layer. As mentioned previously, one method of forming the second GaN epitaxial layer, and other layers described herein, can be through a regrowth process that uses an in-situ etch and diffusion preparation processes, e.g., as described more fully in U.S. patent application Ser. No. 13/198,666, filed on Aug. 4, 2011, the disclosure of which is hereby incorporated by reference in its entirety.

The method further includes forming an in-situ SiN layer, i.e. in the growth reactor, coupled to the second GaN epitaxial layer (2030). The in-situ SiN layer may be deposited according to techniques known in the art, and may include, for example, Si₃N₄, SiNₓ or other suitable compositions.

Portions of the SiN layer, and underlying portions of the second GaN epitaxial layer are removed (2040), e.g. to form one or more diode contact structures or the like. The patterned removal of portions of the SiN layer and the second GaN epitaxial layer may be accomplished, for example, by etching down to an AlGaN layer etch stop layer, if present, and other techniques known in the art.

Additional structures are formed, for example, using deposition and/or patterning and removal processes on the surface of the AlGaN layer, if present, or exposed surfaces of the first or second GaN epitaxial layers (2050). Such structures may include, for example, source and/or drain ohmic contacts, Schottky contacts, metal-insulator stacks, pn junctions or the like. Additional structures may be metallic, such as Ti/Al, dielectrics like silicon nitride, or semiconductor materials including additional III-nitride layers. Remaining portions of the SiN layer may optionally be removed during this process, such as those remaining over portions of the second GaN epitaxial layer to be used for contacts, field plates, or the like.

Additionally, the method includes forming additional metallic structures, e.g., a Schottky gate metal over a remaining portion of the second GaN epitaxial layer (2060). For example, a metallic structure forming a Schottky contact may be formed in contact with the exposed portions of the second conductivity type GaN epitaxial layer. Other structures may also be formed including other types of gates such as pn junctions or MIS capacitor or, for example, various edge termination structures, or the like.

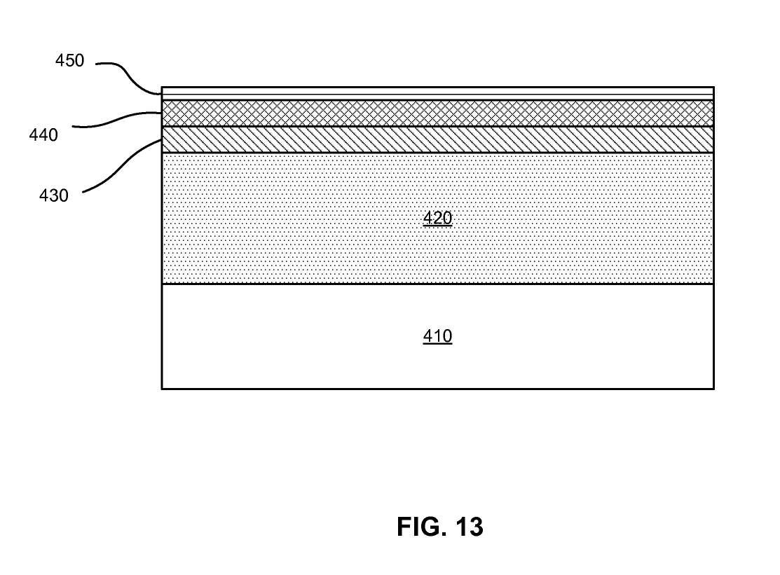

It should be appreciated that the specific steps illustrated in FIG. 12 provide a particular method of fabricating, for example, a HEMT including a AlGaN epitaxial layer, by using an in-situ SiN layer, according to an embodiment of the present invention. Other sequences of steps may also be performed according to alternative embodiments. For example, alternative embodiments of the present invention may perform the steps outlined above in a different order. Moreover, the individual steps illustrated in FIG. 12 may include multiple sub-steps that may be performed in various sequences as appropriate to the individual step. Furthermore, additional steps may be added or removed depending on the particular applications. One of ordinary skill in the art would recognize many variations, modifications, and alternatives. Additional details of an exemplary fabrication process are depicted in FIGS. 13-16.

FIGS. 13-16 are simplified cross-sectional diagrams illustrating the fabrication of a p-GaN Enhancement Mode HEMT using an in-situ SiN layer according to an embodiment of the present invention. As illustrated in FIGS. 13-16 an in-situ SiN layer is used to protect a semiconductor surface during formation of the p-GaN enhancement Mode HEMT. In devices such as this, control of the surface is very important due to the proximity of the device channel to the surface.

As shown in FIG. 13, an HEMT stack structure may include a substrate 410 and a first GaN epitaxial layer 420 coupled to a surface of the substrate 410. An AlGaN layer 430, which is used to form a 2D electron layer for the HEMT, is disposed on the first GaN epitaxial layer 420 opposite the substrate. A second GaN or AlGaN epitaxial layer 440, which will be used to form part of a pn diode gate, is provided over the AlGaN layer 430. According to aspects of the invention a SiN layer 450 may be applied in-situ to the second GaN epitaxial layer 440 during manufacture of the stack.

The thickness of the AlGaN layer 430 can vary, depending on the process used to form the layer and the device design. In some embodiments, the thickness of the AlGaN layer 430 may be between 20 and 500 Å, for example.

The thickness of the second GaN (or AlGaN) epitaxial layer 440 can vary, depending on the process used to form the layer and the device design. In some embodiments, the thickness of the second GaN epitaxial layer 440 is between 100 Å and 3 μm. In other embodiments, the thickness of the second GaN epitaxial layer 440 is between 0.1 μm and 1 μm.

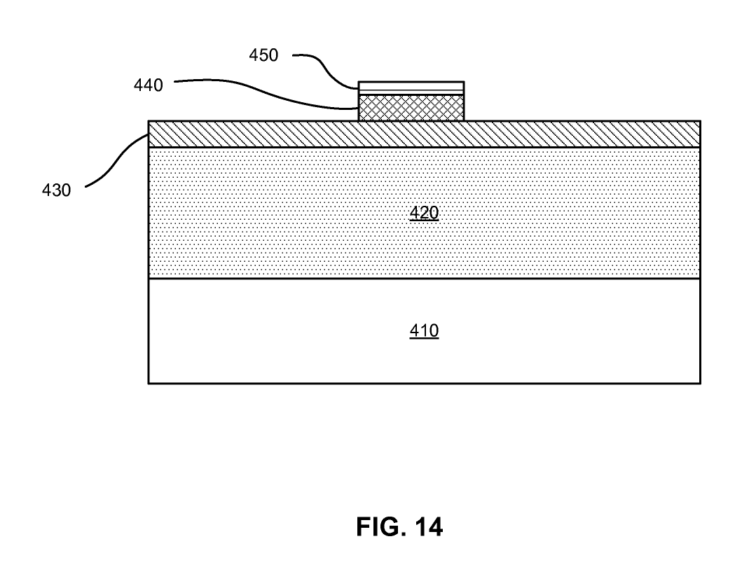

As shown in FIG. 14, portions of the SiN layer 450, and underlying portions of the second epitaxial layer 440, may be removed by etching and other processes known in the art, e.g. to form one or more Schottky contact structures and the like. The patterned removal of portions of the SiN layer 450 and the second GaN epitaxial layer 440 may be accomplished, for example, by etching down to the AlGaN layer 430.

The removal can be performed by a controlled etch using an etch mask (not shown but having the dimensions of the remaining portions of SiN layer 450 and second epitaxial layer 440) designed to stop at approximately the interface between the second epitaxial layer 440 and the AlGaN layer 430. Inductively-coupled plasma (ICP) etching and/or other common GaN etching processes can be used. In the illustrated embodiment, the material removal process used to remove portions of the SiN layer 450 and second epitaxial layer 440 terminates at the interface of layer 440 and layer 430, however, in other embodiments, the process may terminate at a different depth, for example, extending into or leaving a portion of the AlGaN layer 430 and/or first GaN epitaxial layer 420.

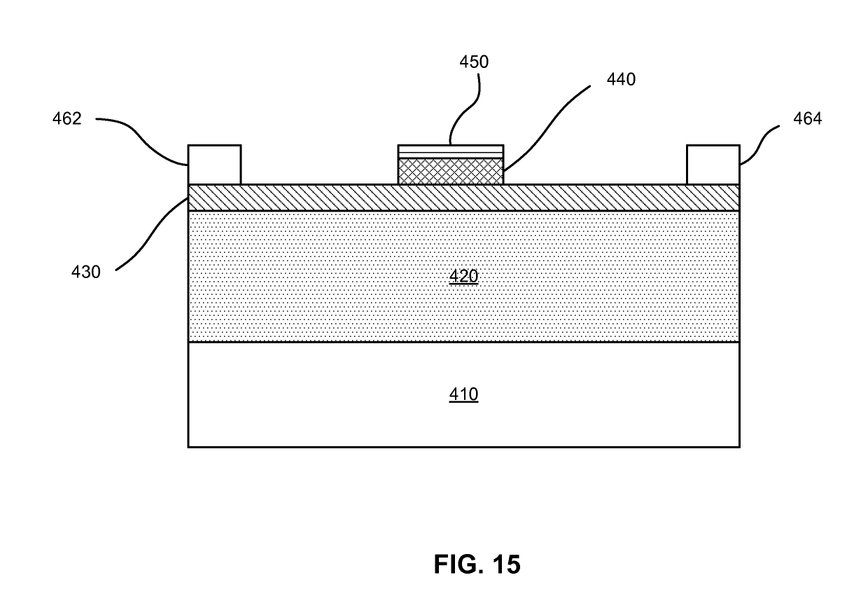

As shown in FIG. 15, additional structures including an ohmic metal source 462 and drain 464 may be formed on the surface of the AlGaN layer 430. Ohmic source 462 and drain 464 may be formed from materials such as TiAl, or other suitable ohmic contacts for AlGaN/GaN HEMTs. Ohmic contact metals may be deposited via sputter deposition, evaporation or chemical vapor deposition (CVD), patterned using photolithographic methods, or the like.

The remaining portions of the SiN layer 450 may be removed prior to subsequent processing and addition of the ohmic metal contact over the second GaN epitaxial layer 440. For example, prior to metal deposition of the ohmic contact, the in-situ SiN can be removed by wet or dry etching using for example, KOH or CF₄ plasma, respectively.

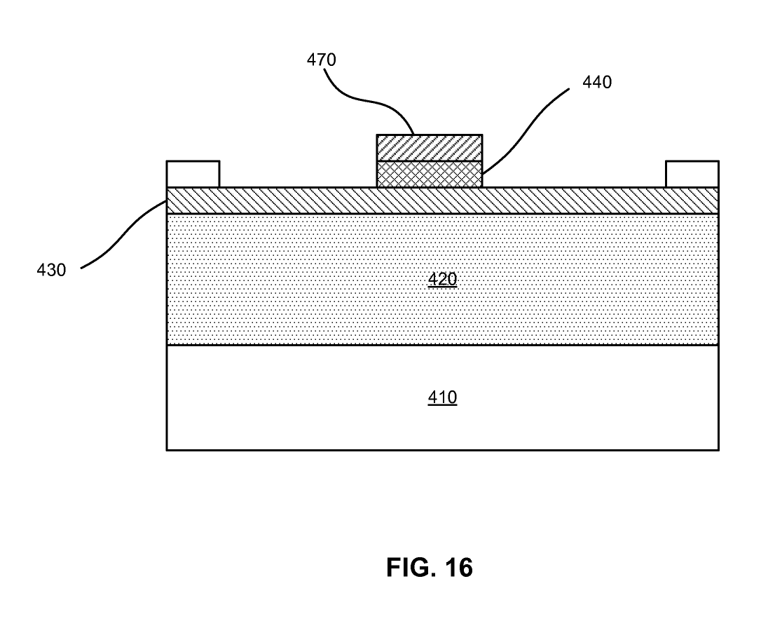

FIG. 16 illustrates formation of a metallic structure 470 on the remainder of the second GaN (or AlGaN) epitaxial layer 440. The metallic structure 470 can be one or more layers of metal and/or alloys to create a ohmic contact with the second GaN (or AlGaN) epitaxial layer 440. The metallic structure 470 can be formed using a variety of techniques, including lift-off and/or deposition with subsequent etching, which can vary depending on the metals used. In some embodiments, the metal structure 470 can include titanium, aluminum, chromium, silver, gold, or the like. As described herein, the SiN LAYER protects the surface from exposure to other processing conditions, such as etch, metal liftoff, photoresist removal.

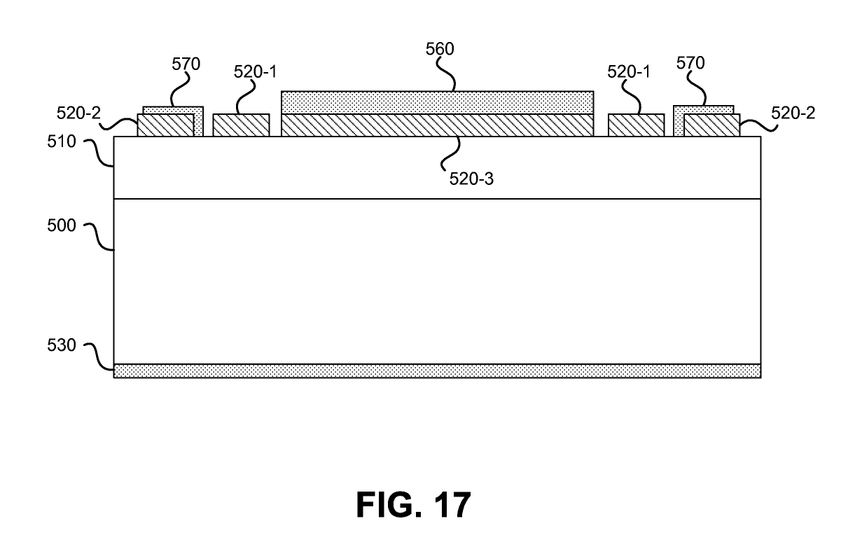

FIG. 17 is a simplified cross-sectional diagram illustrating a PIN diode formed according to an embodiment of the present invention. FIG. 17 depicts yet another embodiment in which techniques including in-situ deposition of a SiN layer may be advantageously used. The structure can include a GaN substrate 500, a first GaN epitaxial layer 510, a second GaN epitaxial layer 520, and a first metallic structure 530. The properties of the structure, such as dopant concentrations and thicknesses, can vary from those of a Schottky diode, depending on desired functionality. For example, the first GaN epitaxial layer 510 can be an intrinsic or very lightly doped layer to function as the intrinsic region of the PIN diode.

The first metallic structure 530 can be one or more layers of ohmic metal that serve as a contact for the cathode of the PIN diode. For example, the metallic structure 530 can comprise a titanium-aluminum (Ti/Al) ohmic metal. Other metals and/or alloys can be used including, but not limited to, aluminum, nickel, gold, combinations thereof, or the like. In some embodiments, an outermost metal of the metallic structure 530 can include gold, tantalum, tungsten, palladium, silver, or aluminum, combinations thereof, and the like. The first metallic structure 530 can be formed using any of a variety of methods such as sputtering, evaporation, or the like.

As shown in FIG. 17, portion of the second GaN epitaxial layer 520 have been removed to form edge termination structures 520-1, 520-2, configured to provide edge termination to the PIN diode. Additionally, as illustrated in FIG. 17, at least a portion of the second GaN epitaxial layer 520 is left, forming a device structure 520-3 with which the PIN diode can be made. For example, in one embodiment, the device structure 520-3 can have a p+ conductivity type, the first GaN epitaxial layer 510 can have a n−conductivity type, and the GaN substrate 500 can have an n+ conductivity type, forming the p, I, and n layers of the PIN diode. As discussed in reference to FIGS. 3, 9 and 14, the removal can be performed by a controlled etch using an etch mask (not shown but having the dimensions of the edge termination structures 520-1 and 520-2) designed to stop at approximately the interface between the second GaN epitaxial layer 520 and the first GaN epitaxial layer 510. Inductively-coupled plasma (ICP) etching and/or other common GaN etching processes can be used.

According to aspects of the invention, a SiN layer may be deposited in-situ during the fabrication process of the device shown in FIG. 17, for example, over the second GaN epitaxial layer 520 before it is separated into the edge termination structures 520-1, 520-2 and device structure 520-3. In embodiments, the in-situ SiN layer may be removed prior to, for example, depositing and/or forming additional metal layers and/or structures such as second metallic structure 560 and metallic field plates 570, discussed further below.

Second metallic structure 560 is electrically coupled to the device structure 520-3. This second metallic structure 560 can be formed using the same techniques used to form the metallic structure 530, and also can include similar metals and/or alloys. The second metallic structure 560 electrically coupled to the device structure 520-3 can serve as an electrical contact (e.g., an anode) for the PIN diode.

As also shown in FIG. 17, metallic field plates 570 may be coupled to an outer edge termination structure 520-2. These metallic field plates 570 can be formed using the same techniques used to form the metallic structures 530, 560, and also can include similar metals and/or alloys. In alternative embodiments, the metallic field plates 570 can be located on any or all of the edge termination structures, and may be coupled to an exposed surface of the first GaN epitaxial layer 510, as shown in FIG. 17. One of ordinary skill in the art would recognize many variations, modifications, and alternatives.

One of ordinary skill in the art would recognize many variations, modifications, and alternatives to the examples provided herein. As illustrated herein, edge termination structures can be provided in a variety of shapes and forms, depending on physical features of the semiconductor device for which the edge termination structures provides its function. For instance, in certain embodiments, edge termination structures may not circumscribe the semiconductor device. Additionally or alternatively, conductivity types of the examples provided herein can be reversed (e.g., replacing an n-type semiconductor material with a p-type material, and vice versa), depending on desired functionality. Moreover, embodiments provided herein using GaN can use other III-nitride materials in addition or as an alternative to GaN. Other variations, alterations, modifications, and substitutions are contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of fabricating a diode in gallium nitride (GaN) materials, the method comprising:
providing a n-type GaN substrate having a first surface and a second surface;
forming a n-type GaN drift layer coupled to the first surface of the n-type GaN substrate;
forming an in-situ SiₓN_{y} layer coupled to the n-type GaN drift layer opposite the n-type GaN substrate;
at least partially removing portions of the SiₓN_{y} layer and the n-type GaN drift layer to form a plurality of void regions and a remaining portion of the SiₓN_{y} layer; and
selectively regrowing a p-type epitaxial layer in the void regions.

2. The method of claim 1 wherein selectively regrowing the p-type epitaxial layer comprises not growing p-type material on the remaining portion of the SiN layer.

3. The method of claim 1 further comprising forming a first metallic structure over portions of the regrown p-type epitaxial layer and the n-type GaN drift layer, wherein the first metallic structure forms a Schottky contact.

4. The method of claim 1 further comprising forming a second Si_{w}N_{z} layer over the regrown p-type epitaxial layer and the n-type GaN drift layer.

5. The method of claim 6 further comprising:
removing a portion of the second Si_{w}N_{z} layer to expose at least part of the p-type epitaxial layer and part of the n-type GaN drift layer; and
forming a Schottky contact coupled to the at least part of the p-type epitaxial layer and the part of the n-type GaN drift layer.

7. The method of claim 1 further comprising forming an oxide layer coupled to the SiₓN_{y} layer.

8. The method of claim 1 wherein x=3 and y=4.

9. The method of claim 1 further comprising forming a Schottky contact over a portion of the n-type GaN drift layer and forming a plurality of guard rings that circumscribe the Schottky contact to provide edge termination.

10. A method of fabricating an epitaxial structure, the method comprising:
providing a III-nitride substrate having a first conductivity type, a first surface, and a second surface opposing the first surface;
forming a first GaN-based epitaxial layer having a first conductivity type and coupled to the first surface of the III-nitride substrate;
forming a second GaN-based epitaxial layer over the first GaN-based epitaxial layer, wherein the second GaN-based epitaxial layer has a second conductivity type;
forming an in-situ protective layer comprising silicon and nitrogen, the in-situ protective layer being coupled to the second GaN-based epitaxial layer opposite the first GaN-based epitaxial layer;
at least partially removing portions of the in-situ protective layer and the second GaN-based epitaxial layer to form at least one gate structure;
removing a remaining portion of the in-situ protective layer; and
forming a first metallic structure coupled to the gate structure.

11. The method of claim 10 wherein the III-nitride substrate comprises a GaN substrate.

12. The method of claim 11 wherein the first conductivity type comprises n-type.

13. The method of claim 10 wherein the first GaN-based epitaxial layer comprises a GaN layer.

14. The method of claim 10 wherein the second GaN-based epitaxial layer comprises a GaN layer.

15. The method of claim 10 wherein the first metallic structure is configured to form an ohmic contact with the second GaN-based epitaxial layer.

16. The method of claim 10 further comprising forming an AlGaN layer between the second GaN-based epitaxial layer and the first GaN-based epitaxial layer.

17. The method of claim 10 further comprising forming one or more edge termination structures.

18. The method of claim 10 further comprising forming a source metal structure and drain metal structure after at least partially removing portions of the in-situ protective layer and the second GaN-based epitaxial layer and prior to removing the remaining portion of the in-situ protective layer.

19. The method of claim 10 wherein the in-situ protective layer comprises Si₃N₄.

20. The method of claim 10 wherein the first conductivity type is n-type and the second conductivity type is p-type.
